(19) United States
(12) Patent Application Publication
(10) Pub. No.: US 2010/0129996 A1
(43) Pub. Date: May 27, 2010

(54) SILICON MATERIAL SURFACE ETCHING FOR LARGE GRAIN POLYSILICON THIN FILM DEPOSITION AND STRUCTURE

(75) Inventor: JIAN ZHONG YUAN, Simi City, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Jian Zhong Yuan, Simi Valley, CA (US)

(21) Appl. No.: 12/431,735

(22) Filed: Apr. 28, 2009

Related U.S. Application Data
(60) Provisional application No. 61/048,540, filed on Apr. 28, 2008.

(51) Int. Cl. H01L 21/306; H01L 21/203; C30B 19/00; H01L 21/205

(52) U.S. Cl. 438/488; 117/58; 257/E21.092; 257/E21.102; 257/E21.215

(57) ABSTRACT

A method of surface treatment for silicon material. The method includes providing a first silicon material having a surface region. The first silicon material has a first purity characteristics and a first surface roughness characteristics. A chemical polishing process is perform to the surface region to cause the surface region to have a second roughness characteristics. Thereafter, a chemical leaching process is performed to the surface region to cause the first silicon material in a depth within a vicinity of the surface region to have a second purity characteristics. A polysilicon material characterized by a grain size greater than about 0.1 mm is formed using a deposition process overlying the surface region.

### CROSS-REFERENCES TO RELATED APPLICATIONS

This application claims priority to U.S. Provisional Application No. 61/048,540, filed Apr. 28, 2008, in the name of Jian Zhong Yuan, and hereby incorporate for reference for all purpose.

### BACKGROUND OF THE INVENTION

The present invention is directed to photovoltaic material. More particularly, the present invention provides a surface treatment method for a silicon material. Merely by way of example, the present method and structure have been applied to photovoltaic cells, but it would be recognized that the invention may be implemented using other materials.

Increasing population growth and industrial expansion have lead to a large consumption of energy. Energy often comes from fossil fuels, including coal and oil, hydroelectric plants, nuclear sources, and others. Almost every element of our daily lives uses fossil fuel, which is becoming increasingly scarce. Accordingly, other alternative sources of energy have been developed to supplement or to replace energy derived from fossil fuels.

Solar energy possesses many desirable characteristics. Solar energy is renewable, clean, abundant, and often widespread. Certain technologies developed often capture solar energy, store it, and convert it into other useful forms of energy, for example, electrical and/or thermal energy.

Solar devices have been developed to convert sunlight into energy. As merely an example, solar thermal panels often convert electromagnetic radiation from the sun into thermal energy for heating homes, running certain industrial processes, or driving high grade turbines to generate electricity. As another example, solar photovoltaic panels convert sunlight directly into electricity for a variety of applications. Accordingly, solar panels have great benefit to human users. They can diversify our energy requirements and reduce the world's dependence on oil and other potentially detrimental sources of energy.

Although solar devices have been used successful for certain applications, there are still certain limitations. For example, solar cells are often composed of silicon bearing wafer materials, which are often costly and difficult to manufacture efficiently on a large scale. Accordingly, there is a limited sources of photovoltaic silicon bearing material. These and other limitations are described throughout the present specification, and may be described in more detail below.

From the above, it is seen that techniques for providing photovoltaic silicon bearing materials is highly desirable.

### BRIEF SUMMARY OF THE INVENTION

The present invention is directed to photovoltaic material. More particularly, embodiments according to the present invention provide a surface treatment method for a silicon material. Merely by way of example, embodiments according to the present invention can be applied to fabrication of photovoltaic devices. But it would be recognized that the present invention has a broader range of applicability.

In a specific embodiment, the method includes providing a first silicon material. The silicon material includes a surface region characterized by a first surface roughness and has a first purity characteristic. The method performs a chemical polishing process to cause a surface region of the first silicon material to have a second surface roughness, the second surface roughness is less than the first surface roughness. The method then performs a chemical leaching process to cause the silicon material in a depth in a vicinity of the surface region to have a second impurity characteristics. The method includes deposition a polysilicon material overlying the surface region. The polysilicon material can have a grain size larger than about 0.1 mm.

Many benefits are achieved by way of present invention over conventional techniques. For example, the present technique provides an easy to use process that relies upon convention technology. In some embodiments, the present method provides a silicon material having a surface characteristics to enable deposition of a polysilicon material characterized by a large grain size, for example, greater than about 0.1 mm. The polysilicon material can be a low cost alternative to the conventional polysilicon material used in photovoltaic device application. Additionally, the method provides a process that is compatible with conventional process technology without substantial modifications to conventional equipment and processes. Depending upon the embodiment, one or more these benefits may be achieved. These and other benefits will be described in more detail throughout the present specification and more particularly below.

### BRIEF DESCRIPTION OF THE DRAWINGS

FIG. 1 is a simplified process flow diagram illustrating a surface treatment method for silicon material according to an embodiment of the present invention.

FIG. 2-5 are simplified diagrams illustrating a surface treatment method for silicon material according to an embodiment of the present invention.

### DETAILED DESCRIPTION OF THE INVENTION

According to embodiments of the present invention, techniques related to photovoltaic materials are provided. More particularly, the present invention provides a surface treatment method for silicon material. Merely by way of example, the present method have been applied to photovoltaic application, but it would be recognized that embodiments according to present invention can have other applications. Further details of the embodiments of the present invention can be found throughout the present specification and more particularly below.

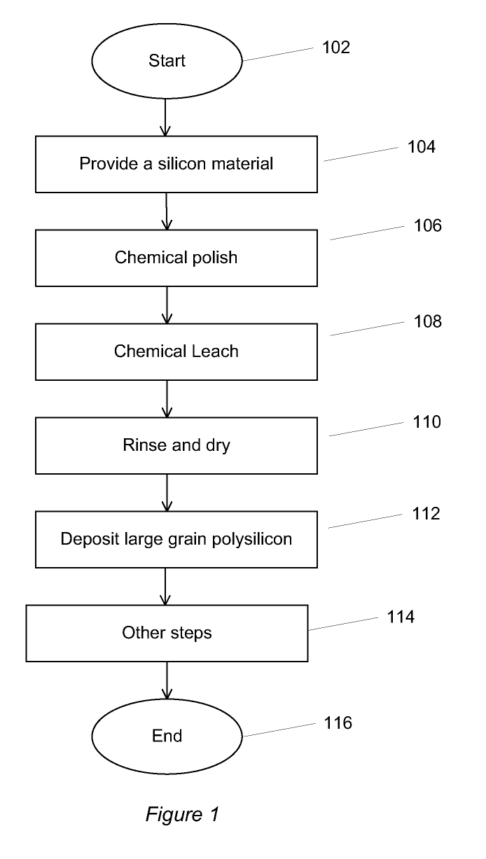

FIG. 1 is a simplified process flow diagram of a surface treatment method for a silicon material according to an embodiment of the present invention. This diagram is merely an example and should not unduly limit the claims herein. One skilled in the art would recognized other modifications, variations, and alternatives. As show, the method includes a start step (Step 102). The method includes providing a silicon material (Step 104) including a surface region. The silicon material is characterized by a first purity. The method performs a chemical polishing process (Step 106) on the surface region. The chemical polishing process removes surface roughness and surface irregularities of the silicon material in a specific embodiment. The method includes using a chemical leaching process to remove impurities from a depth in a vicinity of the surface region (Step 108). The silicon material is then subjected to a rinse and dry process (Step 110) to remove residual chemicals from the surface region. In a specific embodiment, the surface region is suitable for further processing, for example, for deposition of a polysilicon material (Step 112). The polysilicon material is characterized by a large grain size for further fabrication into a photovoltaic device. The method performs other steps as desired.

The above sequence of steps provides a method of forming a silicon material having desirable surface characteristics for depositing a large grain size polysilicon material according to an embodiment of the present invention. As shown, the method uses a combination of steps including a way of surface treatment in a specific embodiment. Other variations and alterations can also be provided where one of more steps are added, one or more steps are removed, or one or more steps are provided in a different sequence without departing form the scope of claims therein. One skilled in the art would recognize many other variations, modifications, and alternatives.

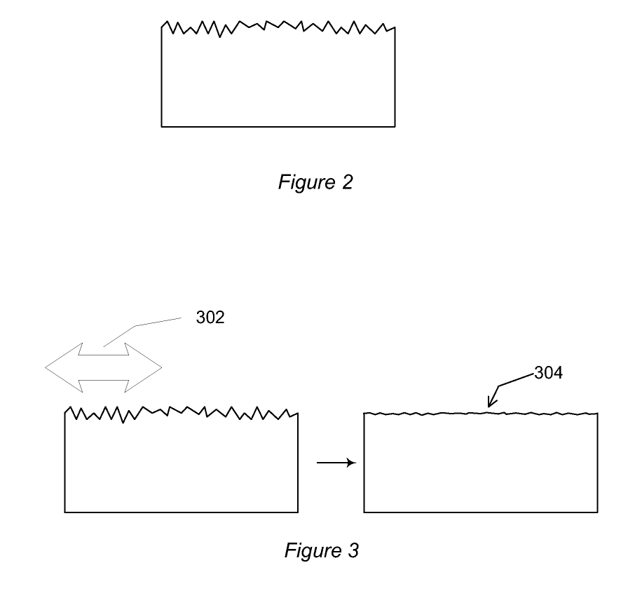

FIGS. 2-5 are simplified diagrams illustrating a method for processing a silicon surface according to an embodiment of the present invention. As shown in FIG. 2, a silicon material 202 is provided. The silicon material can be a polycrystalline silicon material provided as a silicon wafer in a specific embodiment. The silicon material is characterized by a first purity in a specific embodiment. The first purity can be greater than about 2N (0.99 silicon purity) in a specific embodiment.

Referring again to FIG. 2, the silicon material includes a surface region 204. The surface region is characterized by a first surface roughness in a specific embodiment. The surface region can also have certain surface irregularities. The first surface roughness and surface irregularities depends on prior processes, for example, cutting and slicing, crystal pulling, among others. Of course there can be other variations, modifications, and alternatives.

In a specific embodiment, the method includes performing a chemical polishing process 302 on the surface region as shown in FIG. 3. The chemical polishing process can be provided using an alkali to etch the surface region and to remove surface roughness and irregularity. The alkali may include a potassium hydroxide species or an ammonium hydroxide species at a suitable concentration in a specific embodiment. Alternatively, the chemical polishing process may be provided using a suitable acid or acid mixtures. Example of such acid can be a mixture of nitric acid and hydrofluoric acid at a suitable ratio. As shown, the chemical polishing process substantially removes the surface roughness and surface irregularities to provide a surface region 304 suitable for other surface treatment processes.

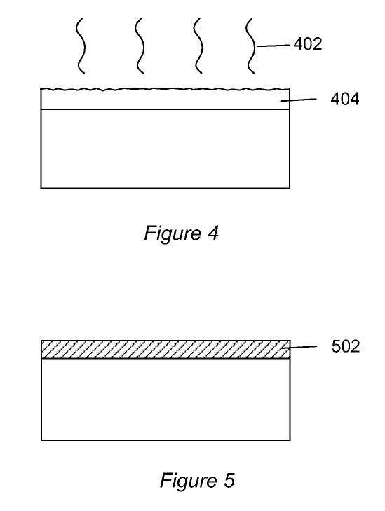

Thereafter, the method performs a chemical leaching process 402 on the surface region of the silicon material as shown in FIG. 4. The chemical leaching process extracts impurities from a depth 404 in a vicinity of the surface region. The silicon material within the depth is characterized by a second purity after the chemical leaching process. The chemical leaching process can use an acid or an acid mixture. For example, a fresh mixture of nitric acid (HNO₃) and hydrochloric acid (HCl) (commonly known as aqua regia or royal water) may be used at room temperature in a specific embodiment. The chemical leaching process can also be provided at an elevated temperature ranging from 45 Degree Celsius to about 55 Degree Celsius depending on the embodiment. Depending on the embodiment, other leaching processed may also be used. Examples of such leaching process can include a diffusion process and the like. Further, depending on the silicon material and the chemical leaching process, the depth of silicon material being leached can range from about 50 microns to about 100 microns. Of course there can be other variations, modifications, and alternatives.

Typically, the silicon material after the chemical leaching process can be subjected to a rinsing process. The rinsing process often uses high purity deionized water to remove residual acids and other undesirable impurities. The silicon material is also dried, for example air dried or other drying methods before further processing. As shown in FIG. 5, the silicon material includes a surface region that is suitable for forming polysilicon material 502 using a deposition process. The deposition process can include epitaxial growth, liquid phase epitaxial growth, chemical vapor deposition, physical vapor deposition and others. In a preferred embodiment, the polysilicon material is characterized by a grain size greater than about 0.1 mm and is suitable for photovoltaic device fabrication. In certain embodiments, the polysilicon material can have a thickness ranging from about 0.1 micron to about 200 microns depending on the application. Of course there can be other variations, modifications, and alternatives.

It is also understood that the examples and embodiments described herein are for illustrative purposes only and that various modifications or alternatives in light thereof will be suggested to persons skilled in the art and are to be included within the spirit and purview of this application and scope of the appended claims.

What is claimed is:

1. A method of surface treatment for silicon material, comprising:
providing a first silicon material having a surface region, the first silicon material having a first purity characteristics and the surface region having a first morphology characteristics;
performing a chemical polishing process to the surface region to cause the surface region to expose one or more crystal planes;
performing a chemical leaching process to the surface region to cause the first silicon material within a depth of the surface region to have a second purity characteristics; and
depositing a polysilicon film material overlying the surface region, the polysilicon film material being characterized by a grain size greater than about 0.1 mm.

2. The method of claim 1 wherein the first silicon material is a polycrystalline silicon material characterized by a grain size greater than about 0.1 mm.

3. The method of claim 1 wherein the first purity characteristic is greater than about N (0.99 pure).

4. The method of claim 1 wherein the chemical polishing process uses potassium hydroxide solution.

5. The method of claim 1 wherein the chemical polishing process uses an acid solution comprising HF and HNO₃.

6. The method of claim 1 wherein the chemical leaching process uses an acid mixture comprising hydrochloric acid and nitric acid.

7. The method of claim 1 wherein the chemical leaching process extracts impurities from the silicon material within the vicinity of the surface region.

8. The method of claim 7 wherein the impurities comprise metallic species

9. The method of claim 1 wherein the chemical polishing process allows for smoothing of the surface region.

10. The method of claim 1 wherein the second purity is higher than the first purity.

11. The method of claim 1 wherein the depth ranges from about 50 microns to about 100 microns.

12. The method of claim 1 wherein the first silicon material has a thickness greater than about 150 microns.

13. The method of claim 1 wherein the polysilicon material is deposited using an epitaxial growth process, a chemical vapor deposition process, a liquid phase epitaxial growth process, or a physical vapor deposition process.

14. The method of claim 1 wherein the polysilicon material has a thickness ranging from about 0.1 micron to about 200 microns
